(19) United States
(12) Patent Application Publication
(10) Pub. No.: US 2016/0365365 A1
(43) Pub. Date: Dec. 15, 2016

(54) THIN-FILM TRANSISTOR, ARRAY SUBSTRATE AND MANUFACTURING METHOD THEREOF, AND DISPLAY DEVICE

(71) Applicant: BOE TECHNOLOGY GROUP CO., LTD., Beijing (CN)

(72) Inventors: Hongwei TIAN, Beijing (CN); Yanan NIU, Beijing (CN); Yueping ZUO, Beijing (CN); Wenqing XU, Beijing (CN); Xiaowei XU, Beijing (CN)

(21) Appl. No.: 15/088,385

(22) Filed: Apr. 1, 2016

(30) Foreign Application Priority Data
Jun. 11, 2015 (CN) 201510319258.2

(51) Int. Cl. H01L 27/12; H01L 29/49; H01L 29/66; H01L 21/02; H01L 29/786

(52) U.S. Cl. CPC H01L 27/1222; H01L 21/02164; H01L 21/02323; H01L 21/0234; H01L 21/0217; H01L 27/1259; H01L 29/78675; H01L 29/78606; H01L 29/66757; H01L 29/4908

(57) ABSTRACT

Embodiments of the present disclosure provide a thin-film transistor (TFT), an array substrate and a manufacturing method thereof, and a display device. The method for preparing a TFT according to an embodiment of the present disclosure may comprise: providing a base substrate; and forming an active layer and an insulation layer on the base substrate. The active layer and the insulation layer may be arranged sequentially and in contact with each other, and the insulation layer may include at least one first insulation layer one of which is in contact with the active layer. The step of forming the first insulation layer may comprise: forming a first insulation film; and conducting a repairing process on the first insulation film by using a repairing source which provides filling atoms, so as to form bonds between at least part of dangling bonds in the first insulation film and the filling atoms.

### CROSS-REFERENCE TO RELATED APPLICATION

This application claims the benefit and priority of Chinese Patent Application No. 201510319258.2 filed Jun. 11, 2015. The entire disclosure of the above application is incorporated herein by reference.

### FIELD

The present disclosure relates to the field of display, and in particular to a thin-film transistor (TFT), an array substrate and a manufacturing method thereof, and a display device.

### BACKGROUND

This section provides background information related to the present disclosure which is not necessarily prior art.

Thin-film transistors (TFTs) have been widely applied in the field of tablet display device nowadays due to their good switching characteristics. A TFT usually includes a gate electrode, an active layer, a source electrode and a drain electrode, in which the source electrode and the drain electrode are arranged at two opposite ends of the active layer and are in contact with the active layer respectively.

In a TFT, the active layer is always in close contact with one insulation layer, which is usually made of silicon oxide. During a manufacturing process of silicon oxide material, a large number of silicon dangling bonds take place at an interface between the silicon oxide and the active layer, which results in all kinds of defects, such as a high interface state density, a lower carrier mobility in the active layer when the TFT turns on, a large fluctuation for sub-threshold voltage Vₜₕ, a large drain current I_{off}, and so forth, thereby electrical performance stability when the TFT turns on deteriorates.

### SUMMARY

This section provides a general summary of the disclosure, and is not a comprehensive disclosure of its full scope or all of its features.

The embodiments of the present disclosure provide a thin-film transistor (TFT), an array substrate and a preparing method thereof, and a display device, which can eliminate effectively interface defects at an insulation layer in contact with an active layer, thereby improving electrical performance stability when the TFT turns on.

Embodiments of the present disclosure provide the following solutions.

According to a first aspect of the present disclosure, provided is a method for preparing a TFT, comprising the following steps: providing a base substrate; and forming an active layer and an insulation layer on the base substrate, wherein the active layer and the insulation layer are arranged sequentially and in contact with each other, and wherein the insulation layer includes at least one first insulation layer one of which is in contact with the active layer, wherein the step of forming the first insulation layer comprises: forming a first insulation film; and conducting a repairing process on the first insulation film by using a repairing source which provides filling atoms, so as to form bonds between at least part of dangling bonds in the first insulation film and the filling atoms.

In one specific embodiment of the present disclosure, the first insulation film may include silicon oxide; the filling atoms may include oxygen atoms; and the dangling bonds may include silicon dangling bonds.

Further, in one specific embodiment of the present disclosure, the repairing source which provides filling atoms may include oxygen plasma.

Further, in one specific embodiment of the present disclosure, the oxygen plasma may include N₂O plasma and/or O₂ plasma.

Further, in one specific embodiment of the present disclosure, the step of forming the first insulation layer may comprise: forming the first insulation film which includes silicon oxide, by using N₂O plasma and SiH₄ plasma as a reaction source; and terminating injection of SiH₄ plasma, while maintaining injection of N₂O plasma within a predetermined time duration, and conducting the repairing process on the first insulation film by using the injected N₂O plasma, so as to form bonds between the silicon dangling bonds in the first insulation film and the oxygen atoms.

Further, in one specific embodiment of the present disclosure, the predetermined time duration may be within a range of 20 s˜80 s.

Further, in one specific embodiment of the present disclosure, the thickness of the formed first insulation film may be within a range of 2 nm˜10 nm.

Further, in one specific embodiment of the present disclosure, the step of forming the insulation layer may further comprise: forming two or three layers of the first insulation layer.

Further, in one specific embodiment of the present disclosure, the step of forming the insulation layer may further comprise: forming a second insulation layer away from the active layer; wherein when the insulation layers are arranged on a side of the active layer away from the base substrate, the step of forming the insulation layers comprises the following step: forming the first insulation layer and the second insulation layer sequentially; or when the insulation layers are arranged on a side of the active layer near the base substrate, the step of forming the insulation layers comprises the following step: forming the second insulation layer and the first insulation layer sequentially.

Further, in one specific embodiment of the present disclosure, the second insulation layer may include silicon oxide and/or silicon nitride.

According to a second aspect of the present disclosure, provided is a method for preparing an array substrate, comprising: a step of forming TFTs on a base substrate; wherein the TFTs are obtained by using any one of the above preparing methods.

According to a third aspect of the present disclosure, provided is a TFT, comprising: an active layer and an insulation layer arranged sequentially on a base substrate and being in contact with each other; wherein the insulation layer comprises: at least one first insulation layer, wherein one of the at least one first insulation layer is in contact with the active layer; wherein the first insulation layer is obtained by conducting a repairing process on a first insulation film by using a repairing source which provides filling atoms; and wherein the repairing process is made for forming bonds between at least part of dangling bonds in the first insulation film and the filling atoms.

Further, in one specific embodiment of the present disclosure, the first insulation film may include silicon oxide; the filling atoms may include oxygen atoms; and the dangling bonds may include silicon dangling bonds.

Further, in one specific embodiment of the present disclosure, the thickness of the first insulation film may be within a range of 2 nm˜10 nm.

Further, in one specific embodiment of the present disclosure, the insulation layer may include two or three layers of the first insulation layer.

Further, in one specific embodiment of the present disclosure, the insulation layer may further comprise a second insulation layer away from the active layer.

Further, in one specific embodiment of the present disclosure, the second insulation layer may include silicon oxide and/or silicon nitride.

Further, in one specific embodiment of the present disclosure, the insulation layer may be gate insulation layer and/or etch stop layer (ESL) of the TFT.

According to a fourth aspect of the present disclosure, provided is an array substrate, which comprises: the above TFTs arranged on a base substrate.

According to a fifth aspect of the present disclosure, provided is a display device, which comprises: the above array substrate.

Based on the above preparing method of the TFT according to embodiments of the present disclosure, when a first insulation layer near an active layer is formed, bonds are formed between dangling bonds in a first insulation film of the first insulation layer and the filling atoms, which results in a repairing process on the first insulation film at an interface, thereby eliminating all kinds of defects, such as a lower carrier mobility in the active layer due to a large number of silicon dangling bonds at the interface when the TFT turns on, a large fluctuation for sub-threshold voltage Vₜₕ, a large drain current I_{off}, and so forth, and improving significantly electrical performance stability when the TFT turns on.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a first sectional structure schematic diagram of a thin-film transistor (TFT) provided by an embodiment of the present disclosure;

FIG. 1B is a second sectional structure schematic diagram of a TFT provided by another embodiment of the present disclosure;

FIG. 1C is a third sectional structure schematic diagram of a TFT provided by still another embodiment of the present disclosure;

FIG. 1D is a fourth sectional structure schematic diagram of a TFT provided by yet still another embodiment of the present disclosure;

FIG. 2 is a structure schematic diagram of a TFT after Step S01 of the manufacturing method thereof according to an embodiment of the present disclosure;

FIG. 3 is a structure schematic diagram of a TFT after Step S02 of the manufacturing method thereof according to an embodiment of the present disclosure;

FIG. 4 is a structure schematic diagram of lattices at an interface of a first insulation film as shown in FIG. 2;

FIG. 5 is a structure schematic diagram of lattices at an interface of a first insulation film 310 in which bonds have been formed between silicon dangling bonds thereof and filling atoms R as shown in FIG. 3;

FIG. 6A is a fifth sectional structure schematic diagram of a TFT provided by an embodiment of the present disclosure;

FIG. 6B is a sixth sectional structure schematic diagram of a TFT provided by another embodiment of the present disclosure; and

FIG. 6C is a seventh sectional structure schematic diagram of a TFT provided by still another embodiment of the present disclosure.

Corresponding reference numerals indicate corresponding parts or features throughout the several views of the drawings.

### REFERENCE SIGNS

01: thin-film transistor; 10: base substrate; 20: active layer; 30: insulation layer; 31: first insulation layer; 310: first insulation film; 32: second insulation layer; 40: gate electrode; 50: inter layer dielectric 61: source electrode; 62: drain electrode.

### DETAILED DESCRIPTION

Example embodiments will now be described more fully with reference to the accompanying drawings.

Unless otherwise defined, any technical or scientific terms used herein shall have the common meaning understood by a person of ordinary skills. Also it is understood that those terms defined in common dictionary should be interpreted as having meanings in coincide with those in the context of the relevant technology, rather than be interpreted to extreme extents, unless otherwise stated herein.

Further, these terms such as “on” used in the Specification and the Claims of the present disclosure only indicate orientations or position relationship shown in the Figures, for the purpose of conveniently illustrating the present disclosure. There is no explicit or implicit requirement that elements or parts described herein have to be arranged at certain orientations, have certain position relationship, or be operated in certain manners, which cannot be regarded as limitations towards the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection.

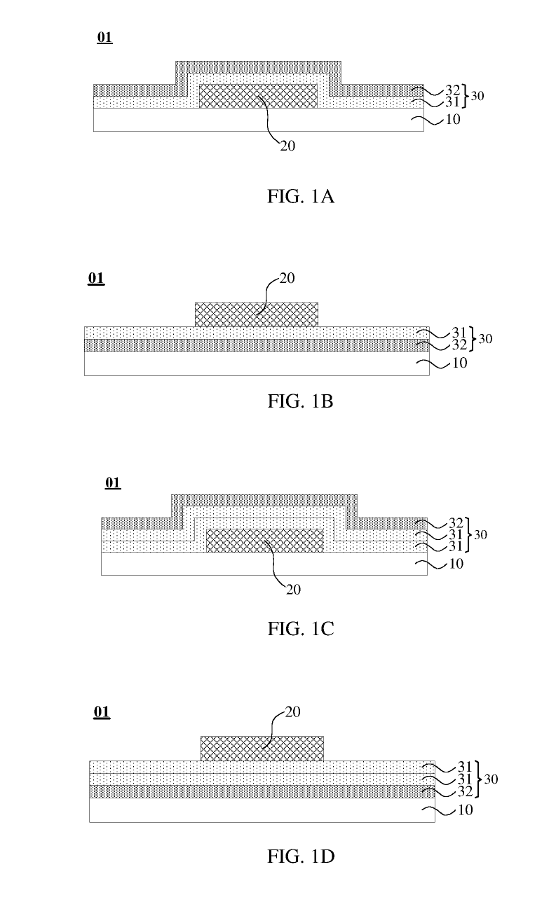

An embodiment of the present disclosure provides a preparing method for a thin-film transistor (TFT) 01. The preparing method may include: as shown in FIG. 1A and FIG. 1B, a step of forming an active layer 20 and an insulation layer 30 arranged sequentially on a base substrate 10 and being in contact with each other. And the step of forming the insulation layer 30 may include: forming at least one first insulation layer 31, wherein one of the at least one first insulation layer 31 is in contact with the active layer 20. Specifically, the step of forming the at least one first insulation layer 31 may include:

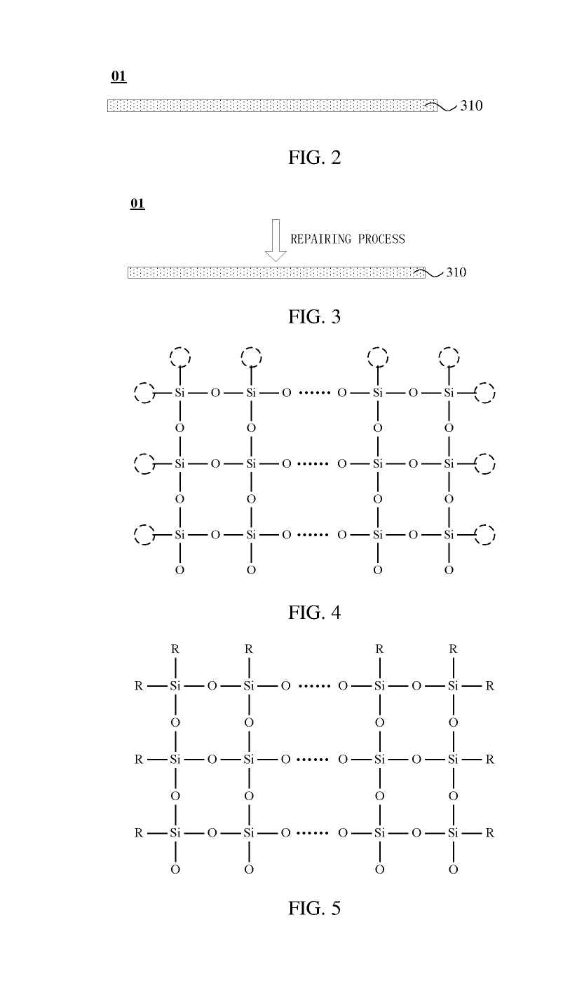

S01, as shown in FIG. 2, forming a first insulation film 310 which includes silicon oxide; and

S02, as shown in FIG. 3, conducting a repairing process on the first insulation film 310 by using a repairing source which provides filling atoms, so as to form the first insulation layer 31 by forming bonds between at least part of silicon dangling bonds in the first insulation film 310 and the filling atoms.

It should be appreciated that the insulations in embodiments of the present disclosure not only include silicon, but also include any other suitable material. On the other hand, the dangling bonds in embodiments of the present disclosure are not limited only to silicon dangling bonds, but also include other forms of dangling bonds. For convenience, hereinafter only silicon dangling bonds are used to describe and illustrate embodiments of the present disclosure.

Prior to detailed description, the following things have to be addressed for better understanding:

First, for better understanding of embodiments of the present disclosure, the term “silicon dangling bonds” mentioned in different embodiments of the present disclosure has to be defined as below.

At an interface of material, due to sudden breakup of lattices at a surface of the material or initial forming of lattices, an unpaired electron, i.e., an unsaturated bond, is formed for each atom at the most outer layer of the surface, which is referred to as “a dangling bond”.

As shown in FIG. 4, at an interface between the formed first insulation film 310 and the active layer 20, silicon atoms (Si) include unsaturated bonds therein (as shown by dotted lines in FIG. 4). As well appreciated, silicon atoms are inclined to have a transition towards a lower-energy and better-structure-stability state, due to the fact that these silicon atoms having unsaturated bonds have a characteristics of high energy and poor structure stability. As a result, these silicon atoms at the interface always tend to form bonds with other atoms to reach more stable structures. Therefore when the above TFT turns on, due to a large number of silicon dangling bonds existed at the interface, these silicon dangling bonds are inclined to snatch atoms out of the active layer 20 so as to form a stable structure, thereby resulting in defects, such as a lower carrier mobility in the active layer of the TFT, a large fluctuation for sub-threshold voltage Vₜₕ, a large drain current I_{off}, and so forth. As a result, electrical performance stability when the TFT turns on deteriorates.

As shown in FIG. 5, in embodiments of the present disclosure, bonds between silicon dangling bonds in the first insulation film 310 and filling bonds (which are indicated by sign R hereinafter) to be bonded with the silicon dangling bonds in the first insulation film 310 are formed, so as to enable silicon atoms at the interface with the active layer 20 to develop a stable structure, thereby eliminating all kinds of defects, such as a lower carrier mobility in the active layer when the TFT turns on, a large fluctuation for sub-threshold voltage Vₜₕ, a large drain current I_{off}, and so forth, and improving significantly electrical performance stability when the TFT turns on.

Herein, the repairing source which provides filling atoms may be gaseous substance, for example plasma. And plasma may be ionized gaseous substance which is consisted of positive and negative ions produced by ionizing atoms and atom groups whose electrons have been partially snatched.

The above filling atoms R may be any atoms which have certain stability after forming bonds with silicon dangling bonds, for example, oxygen atoms, sulfur atoms and so forth. However, embodiments of the present disclosure are not limited thereto.

It should be appreciated that a situation where a repairing process is conducted on silicon dangling bonds shown in FIG. 5 is merely ideal. In fact, not all silicon dangling bonds need to be repaired in the embodiments of the present disclosure, as long as part of silicon dangling bonds form bonds with the above filling atoms R. As compared with conventional methods, TFTs provided according the embodiments of the present disclosure have an improved stability.

Namely, in the embodiments of the present disclosure, it is feasible that either all of silicon dangling atoms or part thereof are repaired by using the filling atoms R, according to repairing amount and its time duration in the above Step S02.

Second, a relative relationship in an up-down direction between an active layer 20 and an insulation layer 30 arranged sequentially and in contact with each other may be adjusted flexibly according to different types of TFTs to be formed. Specifically:

(1) With reference to FIG. 1A, in relation to a base substrate 10, the active layer 20 may be arranged below (under) the insulation layer 30. In other words, the TFT to be formed is a top gate (a gate electrode is located at one side of the active layer away from the base substrate) TFT. In this case, the above insulation layer 30 may specifically be a gate insulation (GI) layer of the TFT which separates and insulates the gate electrode and the active layer 20, or be an etch stop layer (ESL) of the TFT which avoids adverse effect on the active layer 20 when a source electrode and a drain electrode are formed thereon by using an etching process.

(2) With reference to FIG. 1B, in relation to the base substrate 10, the active layer 20 may be arranged above (on) the insulation layer 30. In other words, the TFT to be formed is a bottom gate (the gate electrode is located at the other side of the active layer near the base substrate) TFT. In this case, the above insulation layer 30 may specifically be the GI layer or the ESL of the TFT.

Third, the above steps S01˜S02 may be repeated for a suitable number of times, according to a predetermined thickness requirement for the insulation layer 30 to be formed. Namely several layers of the first insulation layer 31 are to be formed on one side of the insulation layer 30 near the active layer 20.

However too many repetition times of the repairing process on the silicon dangling bonds will not yield any significant improvement, but prolong the whole processing time duration for forming the insulation layer 30 and lower the production efficiency. Therefore in a certain embodiment of the present disclosure, the above steps S01˜S02 may be repeated once or twice. Namely the above insulation layer 30 to be formed may include two or three layers of the first insulation layer 31.

Herein, when the above steps S01˜S02 are repeated once for instance, as shown in FIG. 1C or FIG. 1D, the above insulation layer 30 to be formed may include two layers of the first insulation layer 31. Accordingly, the step of forming each layer of the first insulation layer 31 may include the following steps: forming a first insulation film 310; and conducting the above repairing process thereupon.

Further, as shown in FIG. 1C, when the active layer 20 is arranged below (under) the insulation layer 30 with respect to the base substrate 10, the above two layers of the first insulation layer 31 are arranged above (on) the active layer 20 sequentially, where the one layer of the first insulation layer 31 near the base substrate 10 is in contact with the active layer 20. On the other hand, as shown in FIG. 1D, when the active layer 20 is arranged above (on) the insulation layer 30 with respect to the base substrate 10, the above two layers of the first insulation layer 31 are arranged below (under) the active layer 20 sequentially, where the one layer of the first insulation layer 31 away from the base substrate 10 is in contact with the active layer 20.

Fourth, the first insulation film 310 may be made of silicon oxide, and specific chemical formula of the silicon oxide (SiOₓ) may be SiO, SiO₂, Si₂O₆ and etc. The active layer 20 may be made of low temperature poly silicon (LTPS), oxide semiconductor material and etc. However, embodiments of the present disclosure are not limited thereto. It needs to be noted that silicon oxide is only an example, and the first insulation film 310 is not only limited to silicon oxide, but may be made of other suitable material.

Based on the above manufacturing method of the TFT according to embodiments of the present disclosure, when a first insulation layer 31 near an active layer 20 is formed, bonds are formed between dangling bonds in a first insulation film 310 of the first insulation layer 31 and the filling atoms, which results in a repairing process on the first insulation layer 31 at an interface, thereby eliminating all kinds of defects, such as a lower carrier mobility in the active layer 20 due to a large number of silicon dangling bonds at the interface when the TFT turns on, a large fluctuation for sub-threshold voltage Vₜₕ, a large drain current I_{off}, and so forth, and improving significantly electrical performance stability when the TFT turns on.

On the above bases, in consideration that the first insulation film 310 is made of silicon oxide, such as SiO, SiO₂, Si₂O₆ and etc., in one specific embodiment of the present disclosure, the above filling atoms may be in a same form of element as the first insulation film 310, which may include oxygen atoms, so as to further improve structure stability of the silicon oxide in the first insulation film 310.

Furthermore, the above step S02 may specifically include: repairing silicon dangling bonds in the first insulation film 310 by using oxygen plasma, so as to form the first insulation layer 31.

The above oxygen plasma may include N₂O plasma or O₂ plasma, which is not limited thereto. Specifically, plasma may be ionized gaseous substance which is consisted of positive and negative ions produced by ionizing atoms and atom groups whose electrons have been partially snatched.

Herein, when the first insulation layer 31 to be formed is arranged above (on) the active layer 20 with respect to the base substrate 10, because the first insulation film 310 of the above insulation layer 30 is a part which is formed preliminarily on a surface of the active layer 20, Si—O bonds inside of the first insulation film 310 are in an unstable state, which may be affected by the outside at any timings so as to form new silicon dangling bonds. In embodiments of the present disclosure, a repairing process is conducted on the initially formed first insulation film 310 by using plasma. These unstable Si—O bonds are broken by means of high energy carried by the plasma, such that bonds will be formed between new silicon dangling bonds and oxygen atoms in the oxygen plasma, thereby forming new and stable Si—O bonds.

Therefore it is clear that the embodiments of the present disclosure are more preferably applied to a TFT structure where the active layer 20 is arranged below (under) the insulation layer 30 with respect to the base substrate 10 as shown in FIG. 1A.

Surely, the above step S02 may also be implemented under an oxidizing atmosphere, so as to form bonds between oxygen atoms and unsaturated silicon dangling bonds.

The above step of forming the first insulation layer 31 may be implemented as below, when oxygen plasma is N₂O as an example.

S11, as shown in FIG. 2, forming the first insulation film 310 consisted of silicon oxide by using N₂O plasma and SiH₄ plasma as a reaction source; where the chemical equation is as below:

N₂O(excessive)30 SiH₄→SiOₓ+NH₃;

Here, amount of the injected N₂O plasma is as much as dozens of times amount of the injected SiH₄ plasma, according to insulation performance of the first insulation layer 31 to be formed.

S12, as shown in FIG. 3, terminating injection of SiH₄ plasma, while maintaining injection of N₂O plasma within a predetermined time duration, and conducting the repairing process on the first insulation film 310 by using the injected N₂O plasma, so as to form the first insulation layer 31 by forming bonds between the silicon dangling bonds in the first insulation film 310 and the oxygen atoms.

Here, due to the fact that the first insulation film 310 has not yet stably formed when its thickness is too small and the repairing effect on the first insulation film 310 is reduced when its thickness is too large, a thickness of the formed first insulation film 310 may be within a range of 2 nm˜10 nm in a certain embodiment of the present disclosure.

It should be noted that the above N₂O plasma is also used as a reaction source in a system environment where the first insulation film 310 is formed in step S11, and its density does not vary. Therefore defects of hierarchical structure produced in the first insulation layer 31 can be avoided by conducting the repairing process on the first insulation film 310 in the existing system environment.

Further, the above predetermined time duration may be within a range of 20 s˜80 s. Here, the repairing process is conducted on the first insulation film 310 in the existing system environment in step S12, which is similar to conventional low-rate thin-film deposition process (which usually indicates that film deposition rate is less than 100 Å/s). Therefore when the above predetermined time duration is set to 20 s˜80 s, the whole processing time duration for forming the above insulation layer 30 will not be significantly prolonged, which enables the above methods provided by embodiments of the present disclosure to be applied to actual production.

Further, the above step of forming the insulation layer 30 may include: forming a second insulation layer 32 away from the active layer 20.

Specifically, as shown in FIG. 1A, when the insulation layer 30 is arranged on a side of the active layer 20 away from the base substrate 10, the step of forming the insulation layer 30 may include: forming the first insulation layer 31 and the second insulation layer 32 sequentially. And the second insulation layer 32 may be made of silicon oxide and/or silicon nitride.

Here, when the second insulation layer 32 is made of silicon oxide, injection of SiH₄ plasma may be maintained after the above steps S11˜S12, so as to form the second insulation layer 32 made of silicon oxide, such as SiO, SiO₂, Si₂O₆ and so on.

On the other hand, as shown in FIG. 1B, when the insulation layer 30 is arranged on a side of the active layer 20 near the base substrate 10, the step of forming the insulation layer 30 may include: forming the second insulation layer 32 and the first insulation layer 31 sequentially. And the second insulation layer 32 may be made of silicon oxide and/or silicon nitride.

On the above bases, embodiments of the present disclosure also provide a TFT 01 by using the above manufacturing method. As shown in FIG. 1A or FIG. 1B, the TFT may include: an active layer 20 and an insulation layer 30 arranged sequentially on a base substrate 10 and being in contact with each other. The above insulation layer 30 may include at least one first insulation layer 31, wherein one of the at least one first insulation layer 31 is in contact with the active layer 20. The above first insulation layer 31 is obtained by conducting a repairing process on a first insulation film 310 by using a repairing source which provides filling atoms. The first insulation film 310 may be made of silicon oxide. And the above repairing process is made for forming bonds between at least part of silicon dangling bonds in the first insulation film 310 and the filling atoms R.

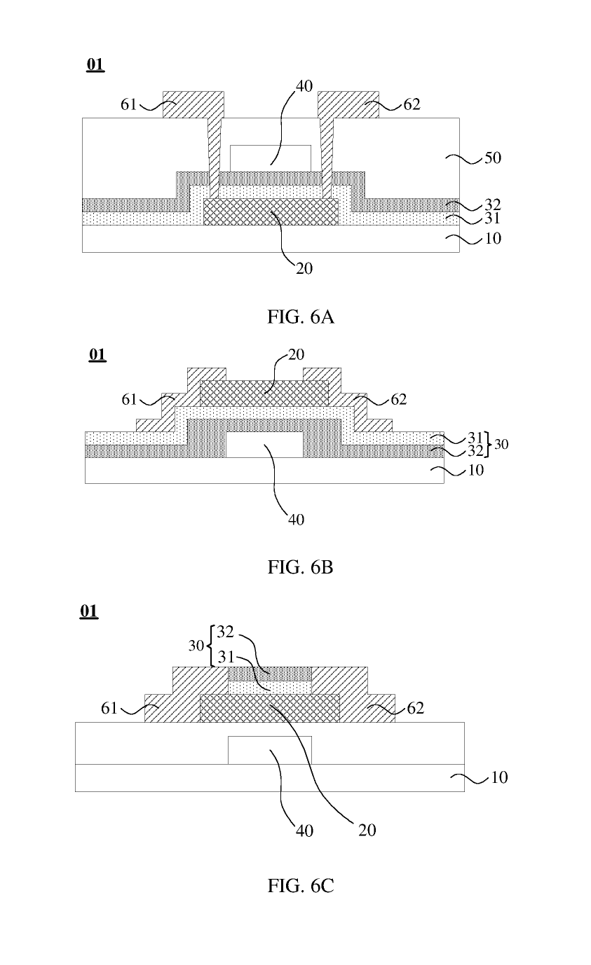

Further, as shown in FIG. 6A, when the above TFT 01 is of a top gate TFT, the above insulation layer 30 may be gate insulation (GI) layer in the TFT 01.

Specifically, the TFT 01 may include a base substrate 10, an active layer 20 thereon, an insulation layer 30, a gate electrode 40, an inter layer dielectric (ILD) 50, a source electrode 61 and a drain electrode 62 sequentially. And the source electrode 61 and the drain electrode 62 may be connected with the active layer 20 through a via hole penetrating the ILD 50 and the insulation layer 30.

Alternatively, as shown in FIG. 6B, when the above TFT 01 is of a bottom gate TFT, the above insulation layer 30 may also be gate insulation (GI) layer in the TFT 01.

Specifically, the TFT 01 may include a base substrate 10, a gate electrode 40 thereon, an insulation layer 30, an active layer 20, a source electrode 61 and a drain electrode 62 sequentially.

Alternatively, as shown in FIG. 6C, when the source electrode 61 and the drain electrode 62 are arranged on a side of the active layer 20 away from the base substrate 10 and in direct contact with the active layer 20 (namely, without need of a via hole), because a wet etching process needs to be performed for patterning the source electrode 61 and the drain electrode 62, the above insulation layer 30 may also be ESL in the TFT 01 for preventing the active layer 20 from etching, in order to avoid etching liquid from being applied to areas on the active layer 20 corresponding to the source electrode 61 and the drain electrode 62 (namely a channel region when the TFT turns on).

Here, the GI layer between the active layer 20 and the gate electrode 40 may also be the above insulation layer 30, whose specific structure will not be elaborated again.

Further, embodiments of the present disclosure also provide a method for preparing an array substrate, which includes a step of forming the above TFT 01 on a base substrate 10.

Further, embodiments of the present disclosure also provide an array substrate which includes the above TFT 01 on the base substrate 10.

Herein, the array substrate needs to include other components like pixel electrodes, common electrodes and so forth, whose specific structure may be conventional and will not be elaborated again.

Further, embodiments of the present disclosure also provide a display device which includes the above array substrate.

Herein, the display device may be not only a display panel, but also a display device including the display panel. The display device may be a liquid crystal panel, an electronic paper, an organic light-emitting diode (OLED) panel, a liquid crystal display (LCD) television, a liquid crystal display (LCD), a digital photo frame, a mobile phone, a tablet computer, and other products or components having the display function.

It can be appreciated that all figures in the present disclosure are simplified diagrams which illustrate the relevant structures of the above TFT and its manufacturing method clearly. As for other structures irrelevant to the embodiments of the present disclosure are conventional and are not shown in these figures, or only a part thereof has not shown therein.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A method for preparing a thin-film transistor (TFT), comprising:
providing a base substrate; and
forming an active layer and an insulation layer on the base substrate, wherein the active layer and the insulation layer are arranged sequentially and in contact with each other, and wherein the insulation layer includes at least one first insulation layer, one of the at least one first insulation layer is in contact with the active layer,
wherein the step of forming the first insulation layer comprises:
forming a first insulation film; and
conducting a repairing process on the first insulation film by using a repairing source which provides filling atoms, so as to form bonds between at least part of dangling bonds in the first insulation film and the filling atoms.

2. The method according to claim 1, wherein the first insulation film includes silicon oxide;
wherein the filling atoms include oxygen atoms; and
wherein the dangling bonds include silicon dangling bonds.

3. The method according to claim 2, wherein the repairing source which provides filling atoms includes oxygen plasma.

4. The method according to claim 3, wherein the oxygen plasma includes N2O plasma and/or O2 plasma.

5. The method according to claim 3, wherein the step of forming the first insulation layer comprises:
forming the first insulation film which includes silicon oxide, by using N2O plasma and SiH4 plasma as a reaction source; and
terminating injection of SiH4 plasma, while maintaining injection of N2O plasma within a predetermined time duration, and conducting the repairing process on the first insulation film by using the injected N2O plasma, so as to form bonds between the silicon dangling bonds in the first insulation film and the oxygen atoms.

6. The method according to claim 5, wherein the predetermined time duration is within a range of 20 s˜80 s.

7. The method according to claim 5, wherein a thickness of the formed first insulation film is within a range of 2 nm˜10 nm.

8. The method according to claim 1, wherein the step of forming the insulation layer further comprises:
forming two or three layers of the first insulation layer.

9. The method according to claim 1, wherein the step of forming the insulation layer further comprises:
forming a second insulation layer away from the active layer;
wherein when the insulation layers are arranged on a side of the active layer away from the base substrate, the step of forming the insulation layers comprises the following step:
forming the first insulation layer and the second insulation layer sequentially; or
when the insulation layers are arranged on a side of the active layer near the base substrate, the step of forming the insulation layers comprises the following step:
forming the second insulation layer and the first insulation layer sequentially.

10. The method according to claim 9, wherein the second insulation layer includes silicon oxide and/or silicon nitride.

11. A method for preparing an array substrate, comprising: a step of forming thin-film transistors (TFTs) on a base substrate;
wherein the TFTs are obtained by using the method according to claim 1.

12. A thin-film transistor (TFT), comprising:
an active layer and an insulation layer arranged sequentially on a base substrate and being in contact with each other;
wherein the insulation layer comprises: at least one first insulation layer, wherein one of the at least one first insulation layer is in contact with the active layer;
wherein the first insulation layer is obtained by conducting a repairing process on a first insulation film by using a repairing source which provides filling atoms; and
wherein the repairing process is made for forming bonds between at least part of dangling bonds in the first insulation film and the filling atoms.

13. The TFT according to claim 12, wherein the first insulation film includes silicon oxide;
wherein the filling atoms include oxygen atoms; and
wherein the dangling bonds include silicon dangling bonds.

14. The TFT according to claim 13, wherein the thickness of the first insulation film is within a range of 2 nm˜10 nm.

15. The TFT according to claim 12, wherein the insulation layer includes two or three layers of the first insulation layer.

16. The TFT according to claim 12, wherein the insulation layer further comprises a second insulation layer away from the active layer.

17. The TFT according to claim 16, wherein the second insulation layer includes silicon oxide and/or silicon nitride.

18. The TFT according to claim 17, wherein the insulation layer is gate insulation layer and/or etch stop layer (ESL) of the TFT.

19. An array substrate, comprising:
thin-film transistors (TFTs) according to claim 12 arranged on a base substrate.

20. A display device, comprising:
the array substrate according to claim 19.
